(19) United States
(12) Patent Application Publication
(10) Pub. No.: US 2016/0369737 A1
(43) Pub. Date: Dec. 22, 2016

(54) INTERNAL-COMBUSTION ENGINE CYLINDER BLOCK AND PRODUCTION METHOD THEREFOR

(71) Applicant: HONDA MOTOR CO., LTD., Tokyo (JP)

(72) Inventors: Koji Kobayashi, Haga-gun, Tochigi-ken (JP); Kaoru Kojina, Haga-gun, Tochigi-ken (JP); Nobuhiko Yoshimoto, Haga-gun, Tochigi-ken (JP); Junya Funatsu, Haga-gun, Tochigi-ken (JP)

(21) Appl. No.: 15/122,329

(22) PCT Filed: Mar. 3, 2015
(86) PCT No.: PCT/JP2015/056243

§ 371 Date: Aug. 29, 2016

(30) Foreign Application Priority Data
Mar. 4, 2014 (JP) 2014-041100

(51) Int. Cl. F02F 1/00; C23C 16/02; H01J 37/32; C23C 16/32; C23C 16/50; F02F 7/00; C23C 16/26

(52) U.S. Cl. CPC F02F 1/004; F02F 7/0085; C23C 16/0245; C23C 16/26; C23C 16/325; C23C 16/50; H01J 37/32009; F02F 2200/00; H01J 2237/334

(57) ABSTRACT

In an internal-combustion engine cylinder block, a SiC interlayer and a DLC film are formed on an inner wall of a cylinder bore. Expressions (1)-(3) are satisfied when T1 is the film thickness of the SiC interlayer and T2 is the film thickness of the DLC film. (1) T1≧0.2 μm. (2) T1<T2. (3) T1+T2≧7 μm. Preferably, 0.2 μm≦T1≦1 μm, and 7 μm≦T1+T2≦13 μm.

### TECHNICAL FIELD

The present invention relates to an internal-combustion engine cylinder block and production method therefor (cylinder block for an internal-combustion engine and a method for producing the same). The cylinder block is used in an internal-combustion engine, a vehicle drive power generation source, and has a cylinder bore along which a piston is slid.

### BACKGROUND ART

An internal-combustion engine for use as drive power in a vehicle contains a cylinder block having a cylinder bore. This type of cylinder block is typically produced by casting and processing a melt of an aluminum alloy.

In general, the aluminum alloy for the cylinder block does not have a high abrasion resistance. Therefore, in a conventional technology, a cylinder liner (or a cylinder sleeve) composed of an Al—Si alloy with an excellent abrasion resistance is placed in the cylinder bore, whereby a piston is slid along the cylinder liner. In contrast, in a recently proposed technology, an inner wall of the cylinder bore is surface-treated to improve the abrasion resistance and lubricity, whereby the piston is slid along the surface-treated wall. For example, in a technology disclosed in Japanese Laid-Open Patent Publication No. 2006-220018, a sprayed film composed of an iron-based metal material is formed on the inner wall of the cylinder bore and is impregnated with a lubricant.

Alternatively, based on the disclosures of Japanese Patent Nos. 3555844 and 4973971, a diamond-like carbon (DLC) film with excellent lubricity and abrasion resistance may be formed on the inner wall of the cylinder bore. It is recommended in Japanese Patent No. 4973971 that a base is subjected to a preliminary surface treatment such as a chrome plating treatment, a chromium nitride treatment, or a nitridation treatment before the formation of the DLC film to prevent separation of the DLC film from the base.

### SUMMARY OF INVENTION

In the technology described in Japanese Patent No. 3555844, in order to put the DLC film into practical use, it is necessary to control the hydrogen content, nitrogen content, and oxygen content of the DLC film as well as the surface roughness of the DLC film. In the technology described in Japanese Patent No. 4973971, it is essential to make the hydrogen atom concentrations different between an inner portion and the outermost portion of the DLC film. In order to achieve this difference, it is necessary to reduce the hydrogen content in an atmosphere in the process of forming the DLC film.

As described above, in the conventional technologies containing the formation of the DLC film on the slide member, the concentration of a component of the DLC film or the distribution thereof must be controlled. Thus, the conventional technologies are forced to do the complicated management.

In addition, the DLC film is poor in adhesion to metal materials as described above. Therefore, even if the preliminary treatment described in Japanese Patent No. 4973971 is performed, it is still worrying that the DLC film may be peeled off.

A principal object of the present invention is to provide a cylinder block for an internal-combustion engine capable of preventing separation of a DLC film from an inner wall of a cylinder bore.

Another object of the present invention is to provide a method for producing a cylinder block for an internal-combustion engine capable of forming a DLC film on an inner wall of a cylinder bore without complicated management.

According to an aspect of the present invention, there is provided a cylinder block for an internal-combustion engine comprising a block base containing an aluminum alloy, an inner wall of a cylinder bore in the block base being covered with a diamond-like carbon film,

wherein

an intermediate SiC film is formed between the inner wall and the diamond-like carbon film, and

the thickness T1 of the intermediate SiC film and the thickness T2 of the diamond-like carbon film satisfy the following inequalities (1) to (3).

T1≧0.2 μm (1)

T1<T2 (2)

T1+T2≧7 μm (3)

According to another aspect of the present invention, there is provided a method for producing a cylinder block for an internal-combustion engine having a block base containing an aluminum alloy, an inner wall of a cylinder bore in the block base being covered with a diamond-like carbon film,

wherein

the method comprises, in a plasma chemical vapor deposition process using the block base as a negative electrode and using a first closing member and a second closing member for closing the cylinder bore as a positive electrode,

a film formation step of supplying an SiC source gas to the inside of the cylinder bore to form an intermediate SiC film on the inner wall and

a film formation step of stopping the supply of the SiC source gas and of supplying a diamond-like carbon source gas to the inside of the cylinder bore having the intermediate SiC film to form the diamond-like carbon film on the intermediate SiC film,

plasma gases used in the film formation steps have a temperature of 130° C. to 190° C., and

the film formation steps are carried out in such a manner that the thickness T1 of the intermediate SiC film and the thickness T2 of the diamond-like carbon film satisfy the following inequalities (1) to (3).

T1≧0.2 μm (1)

T1<T2 (2)

T1+T2≧7 μm (3)

When the thickness T1 of the intermediate SiC film is 0.2 μm or more, the intermediate SiC film is strongly bonded to the block base, i.e. the inner wall of the cylinder bore (the aluminum alloy). Therefore, the diamond-like carbon (DLC) film is rigidly fixed and is hardly peeled off. In addition, when the total thickness T1+T2 is 7 μm or more, the film stack of the intermediate SiC film and the DLC film is hardly cracked.

Thus, when the above conditions are satisfied, the formed DLC film is hardly peeled or cracked. Furthermore, in this case, it is not necessary to control a concentration or a concentration distribution of a component in the DLC film. Therefore, complicated management is not required during the film formation steps.

In the internal-combustion engine having the cylinder block, the lubricity and abrasion resistance can be maintained for a long time due to the presence of the DLC film formed on the inner wall of the cylinder bore. Consequently, the friction loss in the cylinder is reduced, whereby the fuel efficiency or the like of the internal-combustion engine is improved.

In general, the intermediate SiC film is prepared from an expensive starting material. When the thickness T1 of the intermediate SiC film is excessively large, a high cost is required for forming the film. In view of avoiding the cost increase, the thickness T1 is preferably 1 μm or less. Furthermore, when the total thickness T1+T2 of the film stack is excessively large, side cracks tend to appear in the film stack. Therefore, the total thickness T1+T2 is preferably 13 μm or less. Consequently, it is preferred that the thicknesses T1 and T2 satisfy the inequalities of 0.2 μm≦T1≦1 μm and 7 μm≦T1+T2≦13 μm. It is more preferred that the thickness T1 is not less than 0.4 μm.

It is further preferred that the total thickness T1+T2 satisfies the inequality of 9 μm≦T1+T2≦13 μm. In this case, the film stack can be formed at a relatively low temperature, whereby generation of heat distortion or the like can be prevented in the block base (the aluminum alloy).

The hardness of the DLC film, measured by a nanoindentation method, is preferably 6 to 14 GPa, more preferably 8 to 10 GPa. In this case, generation of an abrasion can be prevented in a piston skirt, which slides in contact with the DLC film, and generation of a crack or the like can be easily prevented in the DLC film.

In general, a fuel is compressed in a combustion chamber, and a top dead center of a piston is closer to the combustion chamber. Therefore, the piston is subjected to a higher sliding resistance (friction resistance) in the vicinity of the top dead center. Hence, it is preferred that the DLC film has a larger thickness at the top dead center than at the bottom dead center. In this case, the cylinder block can exhibit a higher lubricity and thus a reduced friction resistance in the vicinity of the top dead center. In addition, in this case, the heat management can be optimized, whereby the fuel efficiency of the internal-combustion engine can be further improved.

It is preferred that a plasma etching step using an oxygen plasma gas is carried out before at least one of the film formation steps for forming the intermediate SiC film and the DLC film. In this case, the intermediate SiC film or the DLC film is formed on a cleaned base and thereby can be prevented from being contaminated with impurities.

Furthermore, it is more preferred that the plasma gases used in the film formation steps for forming the intermediate SiC film and the diamond-like carbon film have a temperature of 150° C. to 170° C.

### BRIEF DESCRIPTION OF DRAWINGS

FIG. 1 is a schematic longitudinal cross-sectional side view of a cylinder block for an internal-combustion engine according to an embodiment of the present invention.

FIG. 2 is a cross-sectional view of an inner wall of a cylinder bore in the cylinder block of FIG. 1.

FIG. 3 is a system diagram of a film formation apparatus for forming an intermediate SiC film and a diamond-like carbon (DLC) film.

FIG. 4 is a graph showing the relationships between the SiC film thicknesses and the exposed base areas in a Rockwell indentation test for samples, each of which contains an aluminum alloy and a SiC film formed thereon.

FIG. 5 is a graph showing the relationships between the film formation temperatures and the scratch test Lc1 values in samples, each of which contains the aluminum alloy and further contains the intermediate SiC film and the DLC film having constant thicknesses formed thereon.

FIG. 6 is a graph showing the relationships between the film formation temperatures and the scratch test Lc1 values in samples, each of which contains the aluminum alloy, the intermediate SiC film having a constant thickness, and the DLC film having a various thickness.

### DESCRIPTION OF EMBODIMENTS

A preferred embodiment of the internal-combustion engine cylinder block and the production method of the present invention will be described in detail below with reference to the accompanying drawings.

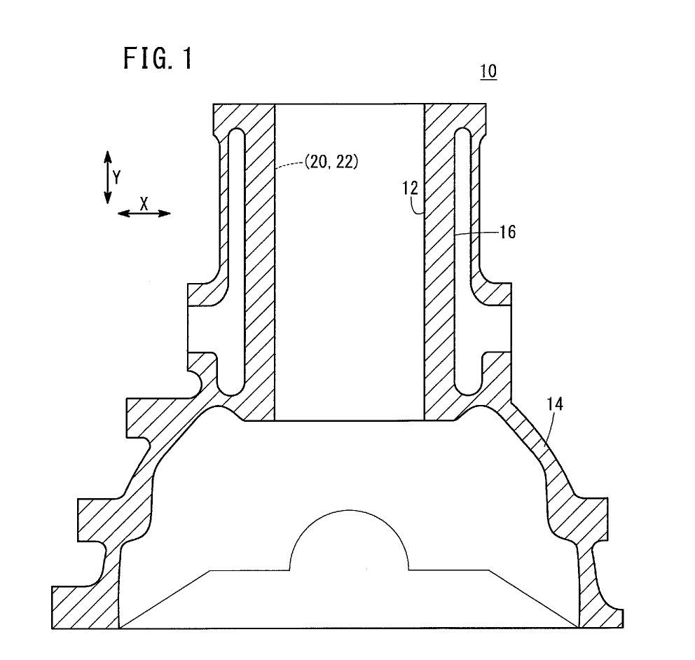

FIG. 1 is a schematic longitudinal cross-sectional side view of a cylinder block 10 for an internal-combustion engine according to this embodiment (hereinafter also referred to simply as the cylinder block). In this embodiment, though the cylinder block 10 is a multicylinder type block having a plurality of cylinder bores 12 arranged, only one of the cylinder bores 12 is shown in FIG. 1.

The cylinder block 10 is a cast product prepared from an aluminum alloy, and is a so-called linerless-type block. A piston (not shown) slides in each cylinder bore 12, and is connected by a connecting rod (not shown) to a crankshaft (not shown) housed in a crankcase 14. Thus, the piston is reciprocated in the cylinder bore 12 with rotation of the crankshaft. A water jacket 16 is formed in the vicinity of the cylinder bore 12, and a cooling water is introduced into the water jacket 16. Such a structure is well known in the art, so a detailed description thereof is omitted.

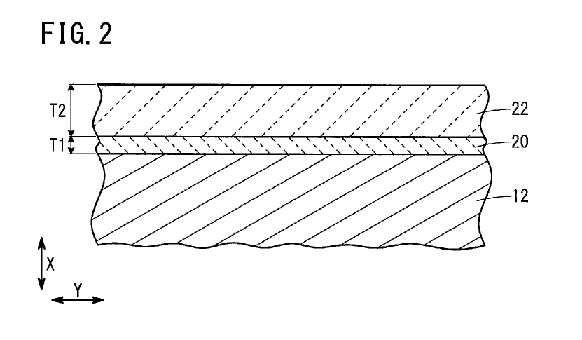

FIG. 2 is a cross-sectional view of an inner wall of the cylinder bore 12. As shown in FIG. 2, an intermediate SiC film 20 and a diamond-like carbon (DLC) film 22 are stacked in this order on the inner wall of the cylinder bore 12. The directions of the arrows X and Y shown in FIG. 2 correspond to those shown in FIG. 1.

The intermediate SiC film 20 is excellent in adhesion to both of the inner wall of the cylinder bore 12 (i.e. the aluminum alloy) and the DLC film 22. Therefore, separation of the DLC film 22 is prevented.

The intermediate SiC film 20 and the DLC film 22 are formed in such a manner that the thickness T1 of the intermediate SiC film 20 and the thickness T2 of the DLC film 22 satisfy the following inequalities (1) to (3). The reason therefor will be described hereinafter.

T1≧0.2 μm (1)

T1<T2 (2)

T1+T2≧7 μm (3)

T1 is not particularly limited as long as it is not less than 0.2 μm and less than T2. The intermediate SiC film 20 is prepared using expensive trimethylsilane as a starting material. Therefore, when T1 is excessively large, a high cost is required for forming the intermediate SiC film 20. In view of avoiding the cost increase, T1 is preferably 1 μm or less.

The total thickness of the intermediate SiC film 20 and the DLC film 22, i.e. T1+T2, is preferably at least 9 μm and not more than 13 μm.

When the DLC film 22 has an excessively high hardness, the toughness of the DLC film 22 may be lowered, and an abrasion scratch may be generated in a piston skirt, which slides in contact with the DLC film 22. On the other hand, when the DLC film 22 has an excessively low hardness, the DLC film 22 tends to have a low stiffness and to be easily cracked. From the viewpoint of avoiding the disadvantages, the hardness of the DLC film 22, measured by a nanoindentation method (referred to also as an ultra-micro indentation hardness test), is preferably 6 to 14 GPa, more preferably 8 to 10 GPa.

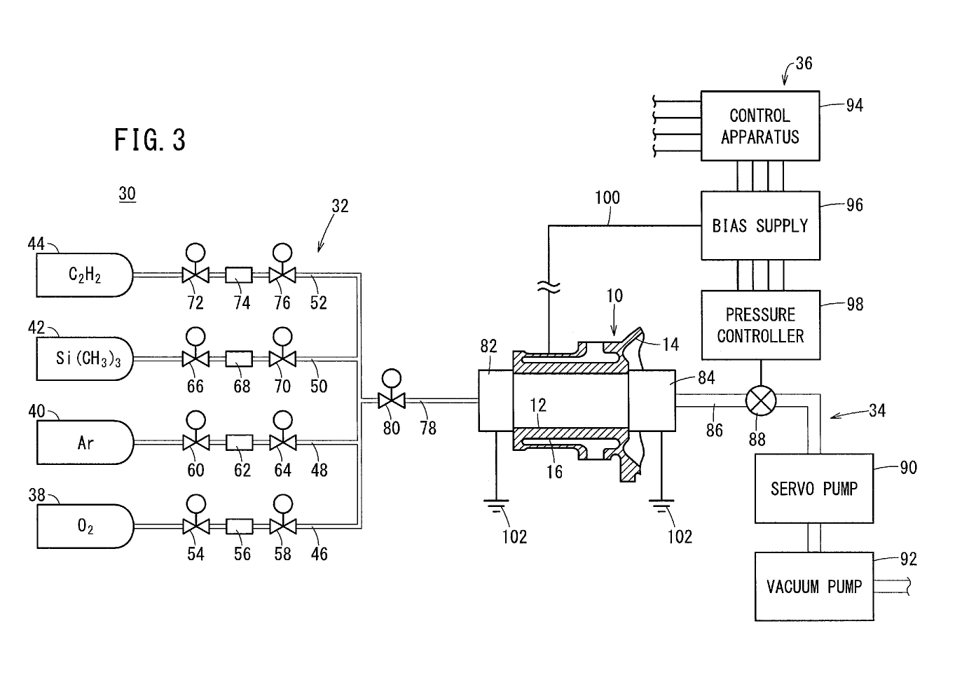

The intermediate SiC film 20 and the DLC film 22 are formed by a plasma chemical vapor deposition (plasma CVD) process using a film formation apparatus 30 shown in the system diagram of FIG. 3. The film formation apparatus 30 has a supply system 32, a discharge system 34, and a control system 36. The supply system 32 and the discharge system 34 are connected to a block base for the cylinder block 10 to seal the cylinder bore 12. The supply system 32 contains a first bomb 38, a second bomb 40, a third bomb 42, and a fourth bomb 44, and further contains a first supply tube 46, a second supply tube 48, a third supply tube 50, and a fourth supply tube 52 connected to the bombs 38, 40, 42, and 44.

The first bomb 38 contains an oxygen (O₂) gas. The second bomb 40 and the third bomb 42 are supply sources of an argon (Ar) gas and a Si(CH₃)₃ (trimethylsilane) gas respectively, and the fourth bomb 44 is a supply source of C₂H₂ (acetylene).

A first valve 54, a first mass flow controller (MFC) 56, and a second valve 58 are disposed on the first supply tube 46 in this order from the upstream side. Similarly, a third valve 60, a second MFC 62, and a fourth valve 64 are disposed on the second supply tube 48 in this order from the upstream side, and a fifth valve 66, a third MFC 68, and a sixth valve 70 are disposed on the third supply tube 50 in this order from the upstream side. Furthermore, a seventh valve 72, a fourth MFC 74, and an eighth valve 76 are disposed on the fourth supply tube 52 in this order from the upstream side.

The first supply tube 46, the second supply tube 48, the third supply tube 50, and the fourth supply tube 52 are collected into one collecting tube 78. A ninth valve 80 is disposed on the collecting tube 78.

The collecting tube 78 is connected to the cylinder bore 12 by a first closing member 82, which acts to close one end of the cylinder bore 12. Of course, a sealant is applied between the block base and the first closing member 82.

The discharge system 34 contains one exhaust tube 86. The exhaust tube 86 is connected to the cylinder bore 12 by a second closing member 84. A control valve 88, a servo pump 90, and a vacuum pump 92 are disposed on the exhaust tube 86. A sealant is applied between the block base and the second closing member 84 in the same manner as between the block base and the first closing member 82.

The control system 36 contains a control apparatus 94 such as a computer, a bias supply 96, and a pressure controller 98. The control apparatus 94 acts to control the bias supply 96 and the pressure controller 98, and further acts to control the first valve 54 to the ninth valve 80, the servo pump 90, and the vacuum pump 92. Thus, by the control apparatus 94, each of the first valve 54 to the ninth valve 80 is opened and closed, and each of the servo pump 90 and the vacuum pump 92 is energized and de-energized.

The bias supply 96 is electrically connected to an outer surface of the block base via a lead 100. A negative bias is applied to the block base by the bias supply 96. Thus, the block base acts as a negative electrode. Meanwhile, each of the first closing member 82 and the second closing member 84 is provided with a grounded (earthed) positive electrode 102.

The pressure controller 98 acts to control the opening of the control valve 88 based on information from a pressure sensor (not shown) disposed on the exhaust tube 86. The inner pressure of the exhaust tube 86 and thus the cylinder bore 12 are controlled in accordance with the opening control.

The intermediate SiC film 20 and the DLC film 22 are formed by using the film formation apparatus 30 as below. The film formation steps will be described in relation to a method for producing the cylinder block 10 according to this embodiment.

First, the control apparatus 94 acts to energize the servo pump 90 and the vacuum pump 92 and to open the control valve 88 to a predetermined extent. Thus, gases are discharged from the exhaust tube 86, the second closing member 84, the cylinder bore 12, the first closing member 82, and the collecting tube 78.

Subsequently, the control apparatus 94 acts to open the first valve 54 and the second valve 58 disposed on the first supply tube 46 and the ninth valve 80 disposed on the collecting tube 78. Then, the oxygen gas supply from the first bomb 38 is started. The flow rate of the oxygen gas is controlled by the first MFC 56.

Before, at, or after the start of the oxygen gas supply, the control apparatus 94 acts to energize the bias supply 96, so that a negative bias is applied to the block base. Incidentally, the grounded positive electrode 102 is formed on the first closing member 82. Therefore, the first closing member 82 acts as a negative electrode, and the oxygen gas is converted to the plasma state to generate an oxygen plasma gas in the first closing member 82. Because a predetermined amount of energy is applied to the oxygen gas in the plasma conversion, the temperature of the generated oxygen plasma gas is higher than that of the oxygen gas.

The inner walls of the first closing member 82 and the cylinder bore 12 are cleaned by the oxygen plasma gas having such a high temperature. Thus, a so-called plasma etching step is carried out. Incidentally, the grounded positive electrode 102 is formed also on the second closing member 84. Therefore, the inner wall of the second closing member 84 is cleaned by the oxygen plasma gas similarly. The cleaning time may be selected depending on the volume of the cylinder bore 12, but about 30 seconds after the start of the oxygen gas supply will be sufficient.

After the elapse of a predetermined time, the control apparatus 94 acts to close the first valve 54 and the second valve 58. Immediately after the closing, the third valve 60, the fourth valve 64, the fifth valve 66, and the sixth valve 70 are opened, so that the argon gas and the trimethylsilane gas are supplied from the second bomb 40 and the third bomb 42 respectively. The flow rates of the argon gas and the trimethylsilane gas are controlled by the second MFC 62 and the third MFC 68 respectively.

The argon gas is converted to the plasma state by the block base used as the negative electrode under the negative bias and the grounded positive electrode 102 formed on the first closing member 82. The trimethylsilane gas is converted to the plasma state similarly. Thus, an argon plasma gas and a trimethylsilane plasma gas are generated. The temperatures of the argon plasma gas and the trimethylsilane plasma gas are controlled within a range of 130° C. to 190° C., preferably at 150° C. The temperatures are controlled by changing the voltage applied to the block base, by using a heater, etc.

The trimethylsilane plasma gas and the argon plasma gas are active gases, whereby an active SiC is generated from the trimethylsilane. The generated SiC is electrically drawn and attached to the block base used as the negative electrode. This phenomenon is successively continued to form the intermediate SiC film 20.

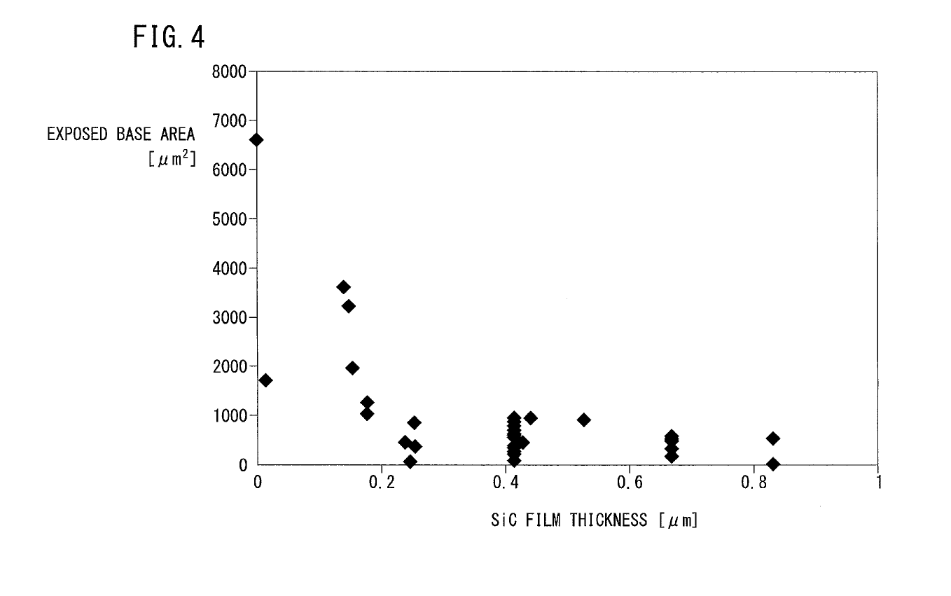

The Rockwell indentation test results of samples, each of which contains the aluminum alloy and a SiC film formed thereon, are shown in FIG. 4 in relation to the SiC film thicknesses. In this test, a diamond is used as an indenter under an applied load of 6.25 kg. In observation of the resultant indentation, when the SiC film is peeled off and the block base (the aluminum alloy) is exposed, the exposed area is calculated.

The test results, i.e. the exposed base areas for various SiC film thicknesses, are shown in FIG. 4. A smaller exposed base area corresponds to a stronger connection (adhesion) between the SiC film and the block base.

As is clear from FIG. 4, the samples with SiC film thicknesses of less than 0.2 μm tend to exhibit large exposed areas, while the samples with SiC film thicknesses of 0.2 μm or more exhibit exposed areas of at most 1000 μm² stably. For this reason, the thickness T1 of the intermediate SiC film 20 (see FIG. 2) is 0.2 μm or more, further preferably 0.4 μm or more. The thickness T1 of the intermediate SiC film 20 is not particularly limited as long as it is not less than 0.2 μm and less than the thickness T2 of the DLC film 22. However, as described above, since the expensive trimethylsilane is used as the starting material for the SiC film, the thickness T1 is preferably 1 μm or less in order to avoid the cost increase.

Whether the thickness T1 of the intermediate SiC film 20 has reached 0.2 μm or not can be judged based on a preliminary film formation test. The preliminary film formation test is carried out under the same film formation conditions to obtain the relationships between the film formation time and the thickness T1 of the intermediate SiC film 20. Thus, the film formation time, at which the thickness T1 reaches 0.2 μm, is obtained in the preliminary film formation test. In the practical formation of the intermediate SiC film 20, the thickness T1 is judged to reach 0.2 μm at the obtained film formation time.

After the elapse of a predetermined time, the control apparatus 94 judges that the formation of the intermediate SiC film 20 is completed. Then, the control apparatus 94 acts to close the third valve 60, the fourth valve 64, the fifth valve 66, and the sixth valve 70 and to open the first valve 54 and the second valve 58 again. As a result, particularly the remaining trimethylsilane gas, and a hydrocarbon or the like, a reaction residue, are captured by the oxygen plasma gas inside the first closing member 82 and the second closing member 84. Thus, cleaning by a so-called plasma etching step is carried out.

Thereafter, the control apparatus 94 acts to close the first valve 54 and the second valve 58. Immediately after the closing, the third valve 60, the fourth valve 64, the seventh valve 72, and the eighth valve 76 are opened, so that the argon gas and the acetylene gas are supplied from the second bomb 40 and the fourth bomb 44 respectively. The flow rate of the argon gas is controlled by the second MFC 62 as described above, and the flow rate of the acetylene gas is controlled by the fourth MFC 74.

The argon gas and the acetylene gas are converted to the plasma states in the same manner as above. Thus, an argon plasma gas and an acetylene plasma gas are generated. Also the temperatures of the argon plasma gas and the acetylene plasma gas are controlled within a range of 130° C. to 190° C., preferably at 150° C.

The acetylene plasma gas and the argon plasma gas are active gases, whereby an active carbon is generated from the acetylene. The generated carbon is electrically drawn to, attached to, and deposited on the block base, to form the DLC film 22.

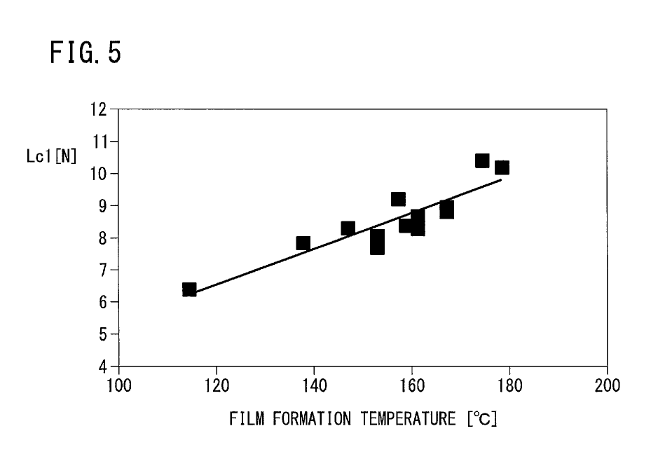

The relationships between the plasma gas temperatures (the film formation temperatures) at which the intermediate SiC film 20 and the DLC film 22 are formed on the aluminum alloy sample and the Lc1 values measured in a known scratch test are shown in FIG. 5. Incidentally, in all the samples, the thickness T1 of the intermediate SiC film 20 is 0.5 μm, and the total thickness T1+T2 of the intermediate SiC film 20 and the DLC film 22 is 10 μm. Thus, only the film formation temperatures are changed in the scratch test.

As is clear from FIG. 5, a higher film formation temperature leads to a larger Lc1 value, i.e. a higher denseness in the DLC film 22.

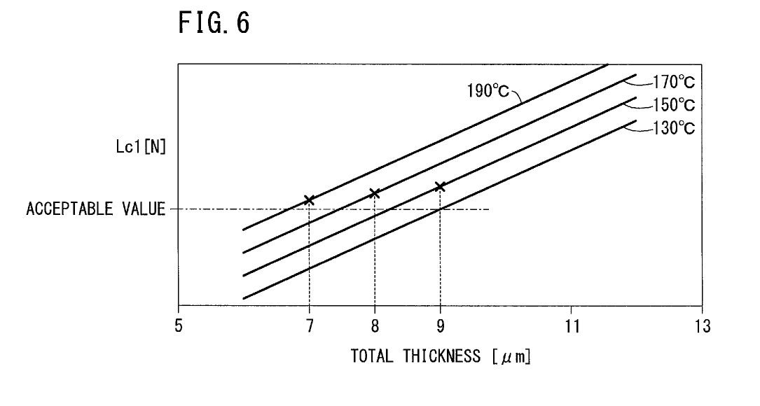

The relationships between the total thicknesses T1+T2 and the Lc1 values under the film formation temperatures of 130° C., 150° C., 170° C., and 190° C. are shown in FIG. 6. Incidentally, also in the samples, the thickness T1 of the intermediate SiC film 20 is 0.5 μm.

As is clear from FIG. 6, a higher film formation temperature leads to a higher denseness and a higher strength of the DLC film 22 even in the samples with small total thicknesses T1+T2. For example, in the case of using a film formation temperature of 190° C., even the sample with a total thickness T1+T2 being about 7 μm exhibits a sufficiently large Lc1 value.

The block base contains the aluminum alloy. As is well known, the aluminum alloy has a low melting point. Therefore, when the film formation temperature is excessively increased, the block base is thermally distorted. Though such heat distortion is not caused at 190° C., it is preferred that the film formation steps are carried out at a temperature of lower than 190° C. to prevent the heat distortion more reliably. For example, a film stack having a total thickness T1+T2 of about 8 to 9 μm prepared at a film formation temperature of 170° C., 150° C., or the like can exhibit an Lc1 value approximately equal to that of a film stack having a total thickness T1+T2 of 7 μm prepared at a film formation temperature of 190° C.

As is clear from FIG. 6, the Lc1 value of the film stack can be increased by increasing the total thickness T1+T2 even under a low film formation temperature. However, when the total thickness T1+T2 exceeds 13 μm, the DLC film 22 is likely to be side-cracked. It is considered that the reasons is that with increase of the thickness of the film stack, the stress in the film stack is increased and the thickness T1 of the intermediate SiC film 20 becomes relatively small, whereby the toughness of the intermediate SiC film 20 is lowered.

When the film formation temperature is excessively lowered, the total thickness T1+T2 has to be increased to more than 13 μm to obtain the film stack with a sufficiently large Lc1 value. In this case, the film stack is likely to be side-cracked as described above, so that a sufficient lubricity is hardly maintained. In addition, the film formation time has to be prolonged to obtain such an increased thickness, so that the consumption of the starting material such as the acetylene gas is increased uneconomically.

For the reasons above, it is preferred that the film formation temperature is about 150° C. to 170° C. and the total thickness T1+T2 is 7 to 13 μm. The thickness T2 of the DLC film 22 is larger than the thickness T1 of the intermediate SiC film 20.

After the elapse of a predetermined time, the control apparatus 94 judges that the formation of the DLC film 22 is completed. Then, the control apparatus 94 acts to close the third valve 60, the fourth valve 64, the seventh valve 72, and the eighth valve 76. The formation of the intermediate SiC film 20 and the DLC film 22 on the inner wall of the cylinder bore 12 is completed in this manner.

Thereafter, the ninth valve 80 and the control valve 88 are closed, the servo pump 90 and the vacuum pump 92 are de-energized (stopped), and the application of the bias from the bias supply 96 is stopped.

Whether the thickness T2 of the DLC film 22 has reached a predetermined thickness (e.g. 7.5 to 9 μm) or not can be judged based on a preliminary film formation test as in the case of the intermediate SiC film 20. During the formation of the intermediate SiC film 20 and the DLC film 22, the inner pressure of the cylinder bore 12 is maintained approximately constant by adjusting the opening of the control valve 88.

The DLC film 22 formed in the above manner has a hardness of 6 to 14 GPa measured by the nanoindentation method.

When the intermediate SiC film 20 and the DLC film 22 are formed on the inner wall of the cylinder bore 12 in another block base, the first closing member 82 and the second closing member 84 are attached to the other block base to close the cylinder bore 12, and then the plasma etching step is carried out in the same manner as above using the control apparatus 94.

Thus, the control apparatus 94 acts to open the first valve 54 and the second valve 58. As a result, the remaining acetylene gas and a carbon or the like, the reaction residue, are captured and cleaned by the oxygen plasma gas inside the first closing member 82 and the second closing member 84.

Then, the intermediate SiC film 20 is formed. The inside space between the first closing member 82 and the second closing member 84 is cleaned in the plasma etching step as described above. Therefore, the intermediate SiC film 20 can be prevented from being mixed with impurities and thus from being contaminated in the film formation step.

The piston is subjected to a higher sliding resistance in the vicinity of the top dead center of the piston (i.e. a position closer to a combustion chamber). It is preferred that the thickness T2 of the DLC film 22 is larger at the top dead center's side than at the bottom dead center's side. In this way, the heat management of the combustion chamber can be optimized, whereby the fuel efficiency of the internal-combustion engine can be improved.

To form such a film, the film formation speed is increased in the vicinity of the top dead center. For example, an end of the block base at a cylinder head's side is heated by using a heater or the like.

1. A cylinder block for an internal-combustion engine comprising a block base containing an aluminum alloy, an inner wall of a cylinder bore in the block base being covered with a diamond-like carbon film,
wherein
an intermediate SiC film is formed between the inner wall and the diamond-like carbon film, and
the thickness T1 of the intermediate SiC film and the thickness T2 of the diamond-like carbon film satisfy the following inequalities (1) to (3):
T1≧0.2 μm, (1)
T1<T2, (2)
T1+T2≧7 μm. (3)

2. The cylinder block according to claim 1, wherein the thicknesses T1 and T2 satisfy the inequalities of 0.2 μm≦T1≦1 μm and 7 μm≦T1+T2≦13 μm.

3. The cylinder block according to claim 2, wherein the thicknesses T1 and T2 satisfy the inequality of 9 μm≦T1+T2≦13 μm.

4. The cylinder block according to claim 1, wherein the diamond-like carbon film has a hardness of 6 to 14 GPa measured by a nanoindentation method.

5. The cylinder block according to claim 4, wherein the diamond-like carbon film has a hardness of 8 to 10 GPa measured by the nanoindentation method.

6. The cylinder block according to claim 1, wherein the diamond-like carbon film has a larger thickness at a side of a top dead center of a piston than at a side of a bottom dead center of the piston.

7. A method for producing a cylinder block for an internal-combustion engine having a block base containing an aluminum alloy, an inner wall of a cylinder bore in the block base being covered with a diamond-like carbon film,
wherein
the method comprises, in a plasma chemical vapor deposition process using the block base as a negative electrode and using a first closing member and a second closing member configured to close the cylinder bore as a positive electrode,
a film formation step of supplying an SiC source gas to an inside of the cylinder bore to form an intermediate SiC film on the inner wall and
a film formation step of stopping supply of the SiC source gas and of supplying a diamond-like carbon source gas to the inside of the cylinder bore having the intermediate SiC film to form the diamond-like carbon film (22) on the intermediate SiC film,
plasma gases used in the film formation steps have a temperature of 130° C. to 190° C., and
the film formation steps are carried out in such a manner that the thickness T1 of the intermediate SiC film and the thickness T2 of the diamond-like carbon film satisfy the following inequalities (1) to (3):
T1≧0.2 μm, (1)
T1<T2, (2)
T1+T2≧7 μm. (3)

8. The method according to claim 7, wherein a plasma etching step using an oxygen plasma gas is carried out before at least one of the film formation steps.

9. The method according to claim 7, wherein the film formation steps are carried out in such a manner that the thicknesses T1 and T2 satisfy the inequalities of 0.2 μm≦T1≦1 μm and 7 μm≦T1+T2≦13 μm.

10. The method according to claim 9, wherein the film formation steps are carried out in such a manner that the thicknesses T1 and T2 satisfy the inequality of 9 μm≦T1+T2≦13 μm.

11. The method according to claim 7, wherein the plasma gases used in the film formation steps have a temperature of 150° C. to 170° C.
